(19) United States
(12) Patent Application Publication
(10) Pub. No.: US 2003/0136442 A1
(43) Pub. Date: Jul. 24, 2003

(54) Group III-V solar cell

(76) Inventor: Tatsuya Takamoto, Ikoma-gun (JP)

Correspondence Address: NIXON & VANDERHYE, PC, 1100 N GLEBE ROAD, 8TH FLOOR, ARLINGTON, VA, 22201-4714, US

(21) Appl. No.: 10/340,711

(22) Filed: Jan. 13, 2003

(30) Foreign Application Priority Data
Jan. 23, 2002 (JP) 2002-014486 (P)

(51) Int. Cl. H01L 31/00

(52) U.S. Cl. 136/262

(57) ABSTRACT

A group III-V solar cell with GaAs as the main component, superior in radiation resistance, is provided. In a GaAs-based group III-V multijunction type solar cell, the group III-V solar cell is formed of an n type emitter layer and a p type base layer. The optical bandgap of the material forming the p type base layer becomes smaller as a function of approaching the pn junction. The group III-V solar cell has stacked a plurality of solar cells differing in optical bandgap. A group III-V solar cell formed of an n type emitter layer and a p type base layer with GaAs as the main component is stacked. The optical bandgap of the p type base layer becomes smaller as a function of approaching the pn junction.

### BACKGROUND OF THE INVENTION

1. Field of the Invention

The present invention relates to a high-efficiency solar cell for space applications employed as the power source for satellites or the like. Particularly, the present invention relates to a high-efficiency solar cell having tolerance with respect to radiation in extraterrestria space.

2. Description of the Background Art

Solar cells of group III-V such as GaAs may have a thinner solar cell active layer than in an Si solar cell due to its higher solar absorptance. Therefore, even if the diffusion length of minority carriers is short, the loss of minority carriers is small by virtue of the thin solar cell active layer. As a result, high performance can be achieved. This means that reduction in the diffusion length caused by space radiation will not readily affect the performance. The multijunction type solar cell fabricated based on epitaxial growth of group III-V material is effective for energy conversion of sunlight that has a wavelength of a wide energy band. A high-efficiency group III-V solar cell that has a conversion efficiency as high as approximately 30% is now realized. Accordingly, in recent years, the group III-V multijunction type solar cell having radiation resistance and high conversion efficiency has become the main stream of solar cells for space applications.

In such a group III-V multijunction type solar cell, further improvement of radiation resistance is an important factor. One method to improve radiation resistance is to adjust the generating current taking into consideration the balance of the radiation resistance of respective sub cells forming the multijunction. There is also a known method of suppressing reduction in the diffusion length of minority carriers in the sub cells.

A general group III-V multijunction type solar cell is typically formed based on the materials of InGaP/GaAs/Ge. Since an InGaP top cell is superior to a GaAs middle cell in radiation resistance, a 3-junction type solar cell has the radiation resistance improved by reducing the thickness of the InGaP top cell to reduce the current generated thereat. Although the initial efficiency is degraded, the radiation resistance will be improved in such a case. For the purpose of improving the radiation resistance in a GaAs middle cell, the impurity concentration of the base layer is selected to have a gradient, whereby a built-in field is established by the change in the carrier concentration. Although the diffusion length of minority carriers (effective value) will be increased by the built-in field established in the base layer, there is a problem that the minority carrier diffusion length (true value) is degraded by the increase in the impurity concentration. There is also a problem that the potential difference by the change in carrier concentration is as low as approximately 20 mV at most, so that it is difficult to generate a sufficient built-in field.

### SUMMARY OF THE INVENTION

An object of the present invention is to provide a solar cell superior in radiation resistance for space applications by suppressing degradation in the minority carrier diffusion length in a p type base layer to improve radiation resistance for a GaAs-based solar cell such as a GaAs middle cell in a group III-V multijunction solar cell such as InGaP/GaAs/Ge, and for a solar cell of an np junction structure whose performance is greatly affected by the lifetime of the minority carriers in the base layer.

According to an aspect of the present invention, a group III-V solar cell includes an n type emitter layer and a p type base layer. The optical bandgap of the material forming the p type base layer becomes smaller as a function of approaching the pn junction. The change in the optical bandgap of the material forming the p type base layer is preferably at least 20 meV, and the region where the optical bandgap changes is preferably at least 0.3 μm in the thickness direction. Also, the n type emitter layer and p type base layer are preferably formed of a ternary material or quaternary material including GaAs that has an optical bandgap of 0.9-1.4 eV.

The preferable ternary material is InGaAs that has an optical bandgap of 0.9-1.4 eV. When the material of the portion in contact with the n type emitter layer is Inₓ₀Ga₁₋ₓₒAs and the material of the plane opposite to the pn junction is Inₓ₁Ga₁₋ₓ₁As in a p type base layer formed of InₓGa₁₋ₓAs, the relationship of O<x≦0.3 and x0−x1≧0.015 are preferable. Also, the preferable quaternary material is InGaAsP having an optical bandgap of 0.9-1.4 eV. When the material of the portion in contact with the n type emitter layer is Inₓ₀Ga₁₋ₓ₀As_{yo}P_{1-yo} and the material of the plane opposite to the pn junction is Inₓ₁Ga₁₋ₓ₁As_{y1}P_{1-y1} in a p type base layer formed of InₓGa₁₋ₓAs_{y}P_{1-y}, the relationship of 0<x≦0.3 and x0−x1≧0.015 or y1−y0≧0.02 are preferable.

According to another aspect of the present invention, a group III-V solar cell is a multijunction type solar cell having stacked a plurality of solar cells differing in optical bandgap. A group III-V solar cell formed of an n type emitter layer and a p type base layer with GaAs as the main component is stacked. The optical bandgap of the p type base layer becomes smaller as a function of approaching the pn junction. For such a multijunction type solar cell, the dual junction type is preferable. In the case where the multijunction type solar cell is a 3-junction or 4-junction type solar cell, the second solar cell from the light receiving plane side is a group III-V solar cell formed of an n type emitter layer and a p type base layer with GaAs as the main component. The optical bandgap of the p type base layer becomes smaller as a function of approaching the pn junction.

According to the present invention, a solar cell with GaAs as the main component, superior in radiation resistance, can be provided. An example of a dual junction cell according to the present invention is shown in FIG. 7. An example of a 4-junction cell according to the present invention is shown in FIG. 8. In a group III-V multijunction cell, improvement in radiation resistance of the GaAs-based cell is the subject. According to the present invention, a group III-V GaAs-based multijunction cell superior in radiation resistance (dual junction cell (FIG. 7), 3-junction cell (FIG. 6), 4-junction cell (FIG. 8), and the like) can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram showing the manner of reduction of the optical bandgap towards the pn junction in a p type base layer.

FIG. 2 is a sectional view of an epitaxially-grown layer in a conventional GaAs solar cell.

FIG. 3 is a sectional view of an epitaxially-grown layer in an InGaAs solar cell of the present invention.

FIG. 4 shows steps in a fabrication process of a solar cell.

FIG. 5 is a sectional view of an epitaxially-grown layer in a 3-junction type solar cell of the conventional InGaP/GaAs/Ge type.

FIG. 6 is a sectional view of an epitaxially-grown layer in an InGaP/InGaAs/Ge 3-junction type solar cell of the present invention.

FIG. 7 is a sectional view of an epitaxially-grown layer in an InGaP/InGaAs dual junction type solar cell of the present invention.

FIG. 8 is a sectional view of an epitaxially-grown layer in an InGaP/InGaAs/InGaAsN/Ge 4-junction type solar cell of the present invention.

### DESCRIPTION OF THE PREFERRED EMBODIMENTS

The present invention is directed to a GaAs-based solar cell such as a GaAs middle cell in a group III-V multijunction type solar cell, for example an InGaP/GaAs/Ge multijunction type solar cell, having an np junction structure whose performance as a solar cell is greatly affected by the diffusion length of minority carriers in the base layer. The solar cell of the present invention is characterized in that the optical bandgap of the material forming the p type base layer becomes smaller as a function of approaching the pn junction by having a structure of an InGaAs ternary material with In added to an n type emitter layer and a p type base layer, wherein the In composition ratio in the base layer is increased in the direction to the pn junction from the back field layer.

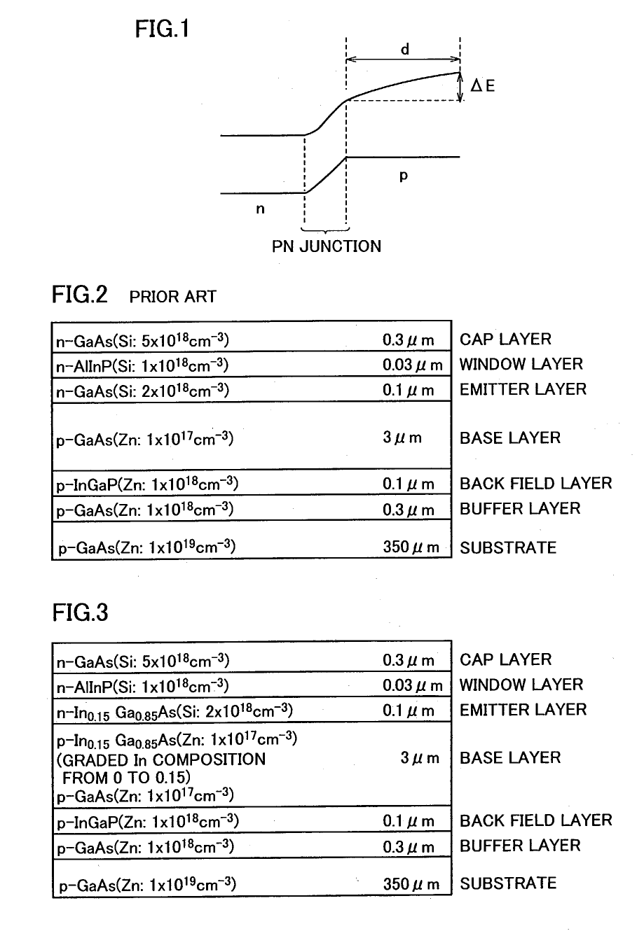

The manner of the optical bandgap becoming smaller towards the pn junction in a p type base layer is shown in FIG. 1. The difference ΔE between the bandgap at the backside of the p type base layer and the bandgap in the neighborhood of the pn junction is preferably at least 20 mV, more preferably at least 100 mV. By setting the bandgap difference ΔE to 100 mV or above, a built-in field is generated having a potential difference of at least 5 times that obtained by the conventional method of establishing a gradient in the impurity concentration. Since a layer of high impurity concentration is not formed, degradation in the diffusion length of minority carriers can be suppressed. Suppression in the diffusion length degradation of minority carriers can be achieved effectively. Thus, a solar cell superior in radiation resistance can be fabricated. In FIG. 1, the region “d” where the optical bandgap changes is preferably at least 0.3 μm, more preferably at least 1 μm in the thickness direction from the standpoint of absorbing at least 90% of solar radiation.

In contrast to the present invention, the conventional approach of increasing the diffusion length of minority carriers by a composition gradient layer is known. Specifically, this method generates a built-in field within the emitter layer and achieves the effect of a window layer in an AlGaAs/GaAs hetero junction type solar cell, for example, by increasing the Al composition ratio of the AlGaAs emitter layer at the light receiving plane side in the direction from the junction towards the light receiving plane to increase the bandgap as a function of approaching the surface. The performance of the solar cell is improved since the diffusion length of minority carriers within the emitter layer increases and the surface recombination velocity is decreased. This method is directed to forming a composition gradient layer in the emitter layer for the purpose of fabricating a solar cell of high efficiency. Therefore, this conventional method differs in function and effect from the method of the present invention that forms a composition gradient layer in the base layer to improve radiation resistance. In the present invention having the bandgap increased at the backside of the base layer, the initial efficiency of the solar cell prior to irradiation is degraded due to the loss caused by transmittance of long wavelength rays.

The n type emitter layer and p type base layer are preferably formed of a ternary material or quaternary material including GaAs that has an optical bandgap of 0.9-1.4 eV. More preferably, the optical bandgap is in the range of 1.0-1.2 eV. If the optical bandgap is smaller than 0.9 eV, the built-in potential generated by the pn junction will be reduced, resulting in a lower voltage of the solar cell. If the optical bandgap is higher than 1.4 eV, less light will be absorbed, resulting in reduction of the current of the solar cell.

As the ternary material including GaAs, InGaAs having an optical bandgap of 0.9-1.4 eV is preferable. The initial efficiency is increased as compared to the conventional InGaP/GaAs/Ge cell by employing an InGaP/InGaAs/Ge cell of the present invention. The bandgap of a conventional InGaP/GaAs/Ge cell is 1.82 eV-1.42 eV-0.67 eV. In this case, the conversion efficiency is calculated at 32%. In contrast, in the InGaP/InGaAs/Ge cell of the present invention, the optimum combination of 1.7 eV-1.2 eV-0.67 eV can be realized by altering GaAs (1.42 eV) to InGaAs (average 1.2 eV) and arranging the InGaP top cell to match the lattice of InGaAs. It is calculated that the conversion efficiency is improved to 36%.

When the material of the portion in contact with the n type emitter layer is Inₓ₀Ga₁₋ₓ₀As and the material at the plane opposite to the pn junction is Inₓ₁Ga₁₋ₓ₁As in a p type base layer formed of InₓGa₁₋ₓAs, x is preferably 0<x≦0.3, more preferably 0.01≦x≦0.2. If the value of x is larger than 0.3, the optical bandgap will become smaller than 0.9 eV. As a result, the voltage of the solar cell will be degraded.

The relationship of x0−x1≧0.015 is preferable, and x0−x1≧0.07 is more preferable. If x1−x1 is lower than 0.015, the potential difference will become lower than 20 mV. The effect of suppressing degradation in the diffusion length of minority carriers will be lost.

As the quaternary material including GaAs, InGaAsP having an optical bandgap of 0.9-1.4 eV is preferable from the standpoint that materials of high quality can be easily obtained and composition control is feasible.

When the material of the portion in contact with the n type emitter layer is Inₓ₀Ga₁₋ₓ₀As_{y0}P_{1-y0} and the material at the plane opposite to the pn junction is Inₓ₁Ga₁₋ₓ₁As_{y1}P_{1-y1} in a p type base layer formed of InₓGa₁₋ₓAs_{y}P_{1-y}, x is preferably 0<x≦0.3, more preferably 0.01≦x≦0.2. If the value of x is higher than 0.3, the optical band will become smaller than 0.9 eV. As a result, the voltage of the solar cell will be degraded.

The relationship of x0−x1 is preferably at least 0.015, more preferably at least 0.07. If value of x becomes lower than 0.015, the potential difference will become smaller than 20 mV. The effect of suppressing degradation in the diffusion length of minority carriers will be lost.

The relationship of y1−y0 is preferably at least 0.02, more preferably at least 0.1. If y1−y0 is lower than 0.02, the potential difference will become smaller than 20 mV. As a result, the effect of suppressing degradation in the diffusion length of minority carriers will be lost.

The group III-V solar cell of the present invention is a multijunction type solar cell having stacked a plurality of solar cells differing in optical bandgap. The solar cell of the present invention is characterized in that a group III-V solar cell formed of an n type emitter layer and a p type base layer with GaAs as the main component is stacked, and the optical bandgap of the p type base layer becomes smaller as a function of approaching the pn junction.

By the above-described solar cell of the present invention, a multijunction type solar cell superior in radiation resistance can be provided.

In the case where the multijunction type solar cell is a dual junction type solar cell, the first or second solar cell from the light receiving plane side has GaAs as the main component.

In the case where the multijunction type solar cell is a 3-junction or 4-junction type solar cell, the second solar cell from the light receiving plane side is preferably a group III-V solar cell formed of an n type emitter layer and a p type base layer with GaAs as the main component, wherein the optical bandgap of the p type base layer becomes smaller as a function of approaching the pn junction. By forming a composition gradient of the present invention in the p type base layer of the second solar cell from the light receiving plane side selected in a multijunction type solar cell, a solar cell improved in conversion efficiency (initial efficiency) and radiation resistance can be obtained. A 3-junction type or 4-junction type solar cell is preferable in terms of obtaining a solar cell of further higher efficiency.

### EXAMPLE 1

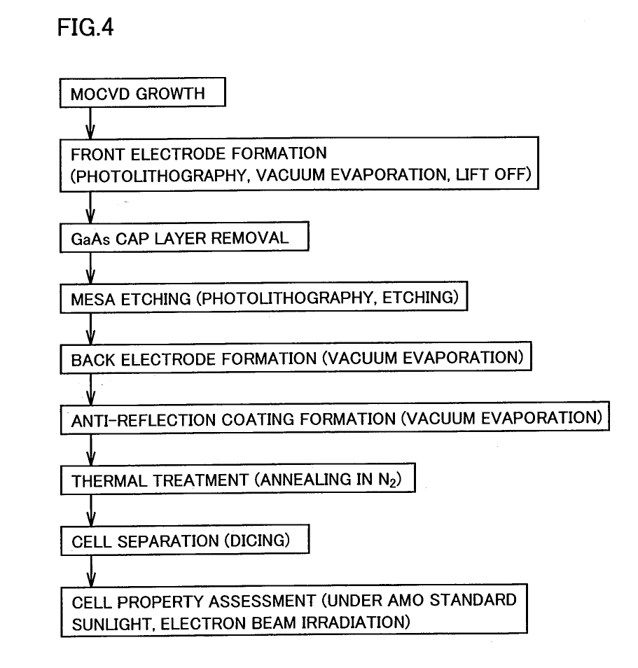

The structure of an epitaxially-grown layer and the thickness of each layer in a fabricated InGaAs solar cell of Example 1 is shown in FIG. 3. The fabrication process of the solar cell is shown in FIG. 4.

First, a layered structure was formed on a p type GaAs substrate through metal organic chemical vapor deposition (MOCVD). Specifically, a GaAs substrate of 100 mm in diameter p type doped with Zn at ×10¹⁹cm⁻³) was placed in a vertical reduced pressure MOCVD apparatus. A layered structure as shown in FIG. 3 was sequentially grown on the substrate. The growth temperature was 700° C. For the growth of a GaAs layer, TMG (trimethyl gallium) and AsH₃ (arsine) were employed as the raw material. For the growth of an InGaP layer, TMI (trimethyl indium), TMG and PH₃ (phosphine) were employed as the raw material. For the growth of an AlInP layer, TMA (trimethyl aluminum), TMI and PH₃ were employed as the base material. For the growth of an InGaAs layer, TMI, TMG and AsH₃ were employed. In the deposition of the InGaAs base layer of the present invention, the flow rate of the TMI evaporation+H₂ carrier gas were linearly altered under mass flow control. Specifically, during the deposition of an InGaAs base layer of 3 μm, the flow rate of TMI evaporation+H₂ carrier gas were altered from 0 up to 75 cc/min. linearly. The In composition ratio was increased 5% at every growth of 1 μm. As a result, a potential difference (ΔE) of 180 mV at most was achieved across the ends of the InGaAs base layer. Throughout the deposition of the GaAs, InGaAs and AlInP layers, SiH₄ (monosilane) was employed as the impurity for formation of the n type layer. For the formation of the p type layer, DEZn (diethylzinc) was employed as the impurity.

A resist with a window corresponding to an electrode pattern was formed by photolithography at the surface of the substrate where an epitaxially-grown layer of a solar cell structure was deposited. Then, the substrate was introduced into a vacuum evaporation system. A layer (thickness 100 nm) of Au including 12% Ge was formed by resistance heating on the substrate with the resist. Then, an Ni layer (thickness 20 nm) and an Au layer (thickness 5 μm) were successively deposited by EB vacuum evaporation. Subsequently, a front electrode of the desired pattern was formed by a lift-off technique.

Using this front electrode as a mask, the portion of the GaAs cap layer where the electrode is not formed was etched with an alkaline solution.

Then, a resist with a window corresponding to a mesa etching pattern was formed by photolithography. The portion of the GaAs layer (InGaAs layer) corresponding to the window was etched with an alkaline solution. The InGaP and AlInP layers were sequentially etched with acid to expose the surface of the substrate.

Then, an Au layer (thickness 100 nm) and an Ag layer (thickness 5 μm) were successively deposited as the back electrode at the backside of substrate through EB vacuum evaporation.

Following formation of the back electrode, a TiO₂ film (thickness 50 nm) and an Al₂O₃ film (thickness 85 nm) were successively formed as an anti-reflection coating at the substrate surface by EB vacuum evaporation.

Then, a thermal treatment of 380° C. was applied in N₂ for the sintering of the front electrode and annealing of the back electrode and anti-reflection coating.

Finally, the cell was cut out based on the dicing line in the mesa-etched line. The size of the cell was 20 mm×20 mm. 12 cells were obtained from one wafer of 100 mm in diameter.

As cell property assessment, the current voltage property in light irradiation was measured by a solar simulator that directs AMO standard sunlight. The open-circuit voltage (Voc), short-circuit current density (Jsc), fill factor (FF) and conversion efficiency (Eft were measured. Then, for radiation resistance assessment, an electron beam (radiation) of 1×10¹⁵ cm⁻² corresponding to one year on stationary orbit was directed onto the cell by dynamitron. The properties after irradiation were evaluated by directing AMO standard sunlight. The cell properties are shown in Table 1. In the table, remaining factor is the rate of the value of each property after electron beam irradiation divided by the value before electron beam irradiation.

TABLE 1

| | Voc(V) | Jsc(mA/cm²) | FF (%) | Eff (%) |
|---|---|---|---|---|
| Example 1 | | | | |
| Before electron beam | 0.95 | 32.1 | 81.5 | 18.4 |
| irradiation | | | | |
| After electron beam | 0.88 | 29.2 | 79.8 | 15.1 |
| irradiation | | | | |
| Remaming factor | 0.93 | 0.91 | 0.98 | 0.82 |
| Comparative | | | | |
| Example 1 | | | | |
| Before electron beam | 1.01 | 30.2 | 82.0 | 18.5 |
| irradiation | | | | |
| After electron beam | 0.91 | 25.4 | 80.3 | 13.6 |
| irradiation | | | | |
| Remaining factor | 0.90 | 0.84 | 0.98 | 0.74 |

### COMPARATIVE EXAMPLE 1

A conventional GaAs solar cell was fabricated in a manner similar to that of Example 1, provided that the emitter layer is an n-GaAs layer of 0.1 μm and the base layer is a p-GaAs layer of 3 μm. The structure of the epitaxially-grown layer and thickness of each layer in the solar cell are shown in FIG. 2. The properties of the cell are shown in Table 1.

It is appreciated from Table 1 that the remaining factor of the In GaAs cell of the present invention subjected to electron beam (radiation) irradiation is significantly higher than the remaining factor of the conventional GaAs cell.

### EXAMPLE 2

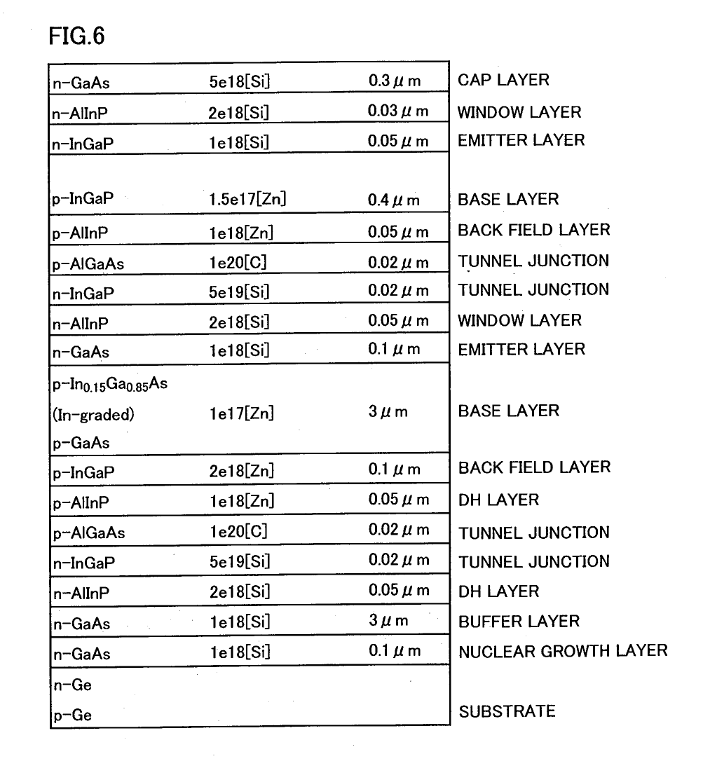

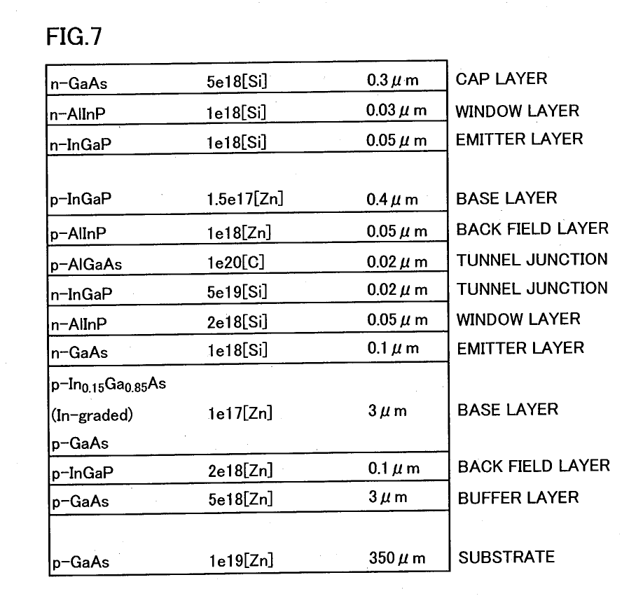

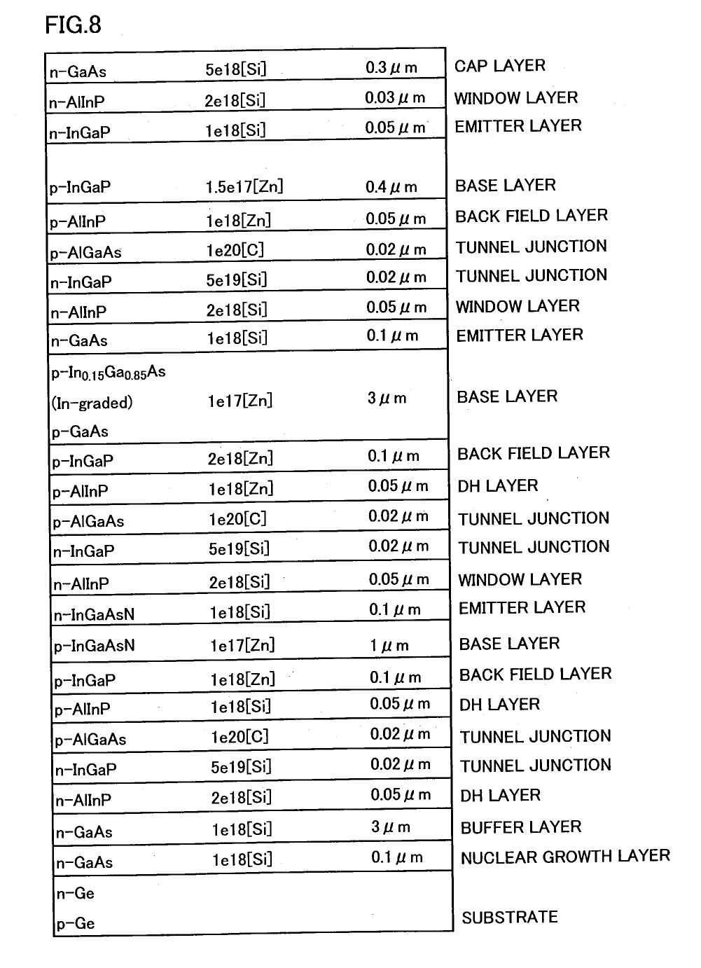

The structure of the epitaxially-grown layer and thickness of each layer in a fabricated InGaP/InGaAs/Ge 3-junction solar cell of Example 2 is shown in FIG. 6.

First, a layered structure was formed on a p type Ge substrate through metal organic chemical vapor deposition (MOCVD). Specifically, a Ge substrate of 100 mm in diameter (p type doped with Ga at 1×10¹⁸ cm⁻³) was placed in a vertical reduced pressure MOCVD apparatus. A layered structure as shown in FIG. 6 was sequentially grown on the substrate. The growth temperature of the GaAs layer which is the first layer to be deposited on the Ge substrate was 600° C. The growth temperature of the other layers in the cell was 700° C. The pn junction in the Ge substrate was naturally formed by the diffusion of As in the first GaAs layer into the Ge substrate to form an n type layer during the growth of the cell layer. For the growth of a GaAs layer, TMG (trimethyl gallium) and AsH₃ (arsine) were employed as the raw material. For the growth of an InGaP layer, TMI (trimethyl indium), TMG and PH₃ (phosphine) were employed as the raw material. For the growth of an AlInP layer, TMA (trimethyl aluminum), TMI and PH₃ were employed as the raw material. Throughout the deposition of the GaAs, InGaP and AlInP layers, SiH₄ (monosilane) was employed as the impurity to form an n type layer. For the formation of a p type layer, DEZn (diethylzinc) was employed as the impurity. Deposition of the p type AlGaAs layer to form a tunnel junction was conducted at the low temperature of 600° C. using TMA TMG, and AsH₃ with CBr₄ as the doping agent. For the growth of an InGaAs layer, TMI, TMG and AsH₃ were employed. In the deposition of the base layer of the InGaAs cell of the present invention, the flow rate of TMI evaporation+H₂ carrier gas was altered linearly under mass flow control. Specifically, in the growth of an InGaAs base layer of 3 μm, the flow rate of TMI evaporation+H₂ carrier gas was altered linearly from 0 to 75 cc/min. The In composition ratio was increased 5% for every growth of 1 μm. As a result, a potential difference (ΔE) of 180 mV at most was achieved across the ends of the InGaAs base layer.

A resist having a window corresponding to an electrode pattern was formed by photolithography at the surface of the substrate where the epitaxial layer of the solar cell structure was grown. The substrate was introduced into a vacuum evaporation system. A layer (thickness 100 nm) of Au including 12% Ge was formed by resistance heating on the substrate with the resist. Then, an Ni layer (thickness 20 nm) and an Au layer (thickness 5 μm) were successively formed by EB vacuum evaporation. Then, a front electrode of a desired pattern was formed by a lift-off technique.

Using the front electrode as a mask, the portion of the GaAs cap layer where the electrode is not formed was etched with an alkaline solution.

Then, a resist with a window corresponding to a mesa etching pattern was formed by photolithography. The GaAs layer (InGaAs layer) and AlGaAs layer corresponding to the window were etched with an alkaline solution. The InGaP and AlInP layers were sequentially etched with acid to expose the surface of the substrate. Then, the mesa portion of the Ge substrate was etched approximately 5 μm using an alkaline solution.

Then, an Au layer (thickness 100 nm) and an Ag layer (thickness 5 μm) were successively formed as the back electrode at the backside of the substrate by EB vacuum evaporation.

Following formation of the back electrode, a TiO₂ film (thickness 50 nm) and an Al₂O₃ film (thickness 85 nm) were successively formed as the anti-reflection coating at the surface of the substrate by EB vacuum evaporation.

Then, a thermal treatment was applied at 380° C. in N₂ for the sintering of the front electrode and annealing of the back electrode and anti-reflection coating.

Finally, the cell was cut out based on the dicing line in the mesa-etched line. The size of the cell was 20 mm×20 mm. 12 cells were obtained from one wafer of 100 mm in diameter.

As cell property assessment, the current voltage property in light irradiation was measured by a solar simulator that directs AMO standard sunlight. The open-circuit voltage (Voc), short-circuit current density (Jsc), fill factor (FF) and conversion efficiency (Eff) were measured. Then, for radiation resistance assessment, an electron beam (radiation) of 1×10¹⁵ cm⁻² corresponding to one year on stationary orbit was directed onto the cell by dynamitron. The properties after irradiation were evaluated by directing AMO standard sunlight. The cell properties are shown in Table 2.

TABLE 2

| | Voc(V) | Jsc(mA/cm²) | FF(%) | Eff(%) |
|---|---|---|---|---|
| Example 2 | | | | |
| Before electron beam | 2.25 | 19.1 | 85.1 | 27.1 |
| irradiation | | | | |
| After electron beam | 2.16 | 18.7 | 82.6 | 24.9 |
| irradiation | | | | |
| Remaining factor | 0.96 | 0.98 | 0.97 | 0.92 |
| Comparative | | | | |
| Example 2 | | | | |
| Before electron beam | 2.56 | 16.1 | 85.8 | 26.1 |
| irradiation | | | | |
| After electron beam | 2.41 | 15.5 | 81.5 | 22.4 |
| irradiation | | | | |
| Remaining factor | 0.94 | 0.96 | 0.95 | 0.86 |

### COMPARATIVE EXAMPLE 2

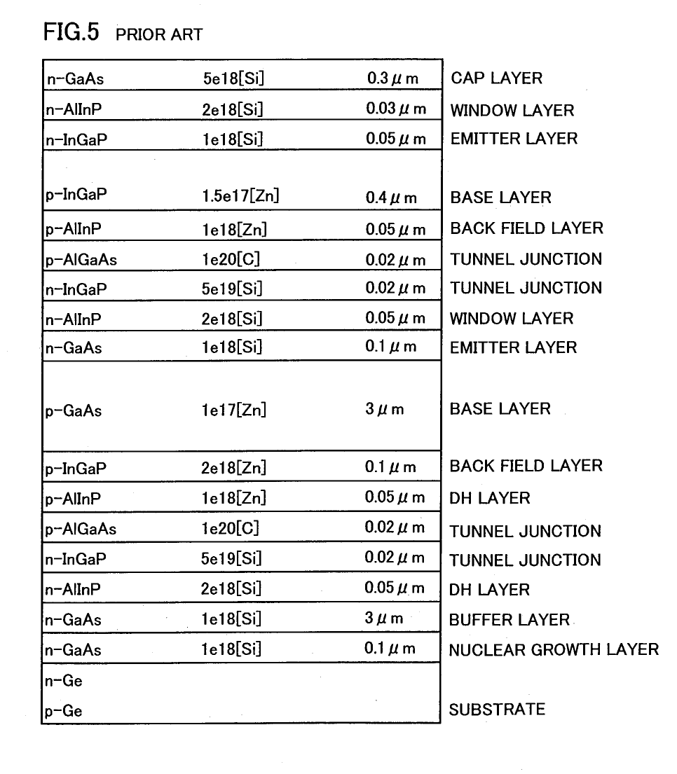

A conventional InGaP/GaAs/Ge 3-junction solar cell was fabricated in a manner similar to that of Example 2 provided that the base layer of the second solar cell from the light receiving plane side was a p-GaAs layer of 3 μm. The structure of the epitaxially-grown layer and thickness of each layer in the solar cell are shown in FIG. 5. The cell properties are shown in Table 2.

The property remaining factor of the InGaP/InGaAs/Ge cell of the present invention subjected to irradiation was greatly improved as compared to the conventional GaAs cell. The reason why the initial efficiency of the cell of the present invention before electron beam irradiation is higher than the initial efficiency of the conventional cell is that the combination of the bandgap is qualified to increase the logic efficiency.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A group III-V solar cell including an n type emitter layer and a p type base layer, wherein an optical bandgap of a material forming said p type base layer becomes smaller as a function of approaching a pn junction.

2. The group III-V solar cell according to claim 1, wherein a change in the optical bandgap of the material forming said p type base layer is at least 20 meV, and a region where said optical bandgap changes is at least 0.3 μm in a thickness direction.

3. The group III-V solar cell according to claim 1, wherein said n type emitter layer and said p type base layer are formed of one of ternary material and quaternary material including GaAs having an optical bandgap of 0.9-1.4 eV.

4. The group III-V solar cell according to claim 3, wherein said ternary material includes InGaAs having an optical bandgap of 0.9-1.4 eV.

5. The group III-V solar cell according to claim 3, wherein said quaternary material includes InGaAsP having an optical bandgap of 0.9-1.4 eV.

6. The group III-V solar cell according to claim 1, wherein, when the material of a portion in contact with the n type emitter layer is Inₓ₀Ga₁₋ₓ₀As and the material at a plane opposite to the pn junction is Inₓ₁Ga₁₋ₓ₁As in a p type base layer of InₓGa₁₋ₓAs, a relationship of 0<x≦0.3 and x0−x1≧0.015 is satisfied.

7. The group III-V solar cell according to claim 1, wherein, when the material of the portion in contact with the n type emitter layer is Inₓ₀Ga₁₋ₓ₀As_{y0}P_{1-y0} and the material at the plane opposite to the pn junction is Inₓ₁Ga₁₋ₓ₁As_{y1}P_{1-y1} in a p type base layer of InₓGa₁₋ₓAs_{y}P_{1-y}, a relationship of 0<x≦0.3, and x0−x1≧0.015 or y1−y0≧0.02 is satisfied.

8. A group III-V solar cell in a multijunction type solar cell having stacked a plurality of solar cells differing in optical bandgap, wherein a group III-V solar cell formed of an n type emitter layer and a p type base layer with GaAs as a main component is stacked, and an optical bandgap of said p type base layer becomes smaller as a function of approaching a pn junction.

9. The group III-V solar cell according to claim 8, wherein said multijunction type solar cell is a dual junction type solar cell.

10. The group III-V solar cell according to claim 8, wherein a second solar cell from a light receiving plane side is a group III-V solar cell formed of an n type emitter layer and a p type base layer with GaAs as a main component, and an optical bandgap of said p type base layer becomes smaller as a function of approaching a pn junction when said multijunction solar cell is one of a 3-junction and 4-junction type solar cell.
